(19) United States
(12) Patent Application Publication
(10) Pub. No.: US 2023/0106612 A1
(43) Pub. Date: Apr. 6, 2023

(54) METHOD OF MANUFACTURING ELECTRICAL PACKAGE

(71) Applicant: Advanced Semiconductor Engineering, Inc., Kaohsiung (TW)

(72) Inventors: Wen-Pin HUANG, Kaohsiung (TW); Fu Tang CHU, Kaohsiung (TW); Pei I CHANG, Kaohsiung (TW); Chia Hao CHEN, Kaohsiung (TW); Tsuan Ching KUO, Kaohsiung (TW)

(73) Assignee: Advanced Semiconductor Engineering, Inc., Kaohsiung (TW)

(21) Appl. No.: 17/494,689

(22) Filed: Oct. 5, 2021

(51) Int. Cl. H01L 21/683; H01L 21/48; H01L 21/78

(52) U.S. Cl. CPC H01L 21/6836; H01L 21/4803; H01L 21/78; H01L 2221/68327; H01L 2221/68331

(57) ABSTRACT

A method for manufacturing an electrical package is provided. The method include: providing a substrate having a first surface and a second surface opposite to the first surface, wherein the second surface has a first level difference; forming an adhesive layer on the second surface of the substrate, wherein the adhesive layer is configured to cover the second surface and provides a third surface spaced apart from the second surface of the substrate, wherein the third surface has a second level difference; disposing a tape on the third surface of the adhesive layer; and performing a removing operation on the first surface of the substrate; wherein the second level difference is smaller than the first level difference.

### BACKGROUND

### 1. Field of the Disclosure

The present disclosure relates to a method of manufacturing an electrical package, in particular to a method applicable to an electrical package including a carrier with uneven surface.

### 2. Description of the Related Art

During grinding, a tape, such as back grind (BG), is used to protect a carrier from moisture or contamination from the carrier. However, when a carrier has an uneven surface, the BG tape cannot conformally attach, resulting in moisture or contamination entering between the carrier and BG tape, degrading the quality of the product.

### SUMMARY

In some embodiments, a method for manufacturing an electrical package includes: providing a substrate having a first surface and a second surface opposite to the first surface, wherein the second surface has a first level difference; forming an adhesive layer on the second surface of the substrate, wherein the adhesive layer is configured to cover the second surface and provides a third surface spaced apart from the second surface of the substrate, wherein the third surface has a second level difference; disposing a tape on the third surface of the adhesive layer; and performing a removing operation on the first surface of the substrate; wherein the second level difference is smaller than the first level difference.

In some embodiments, a method for manufacturing an electrical package includes: providing a substrate having a first surface and a second surface opposite to the first surface, wherein the substrate comprises a plurality of components and a plurality of recesses on the second surface; forming an adhesive layer on the second surface of the substrate, wherein the adhesive layer comprises a material configured to surround the component or fill into the recesses; disposing a tape on the adhesive layer; and performing a removing operation on the first surface of the substrate.

In some embodiments, a method for manufacturing an electrical package includes: providing a substrate having a first surface and a second surface opposite to the first surface, where the second surface has a first unevenness; forming a leveling layer on the second surface of the substrate and configured to provide a third surface having a second unevenness more even than the first unevenness; disposing a carrier on the third surface to support the substrate; and removing at least a portion of the substrate from the first surface of the substrate.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1A, FIG. 1B, FIG. 1C, FIG. 1D, FIG. 1E, FIG. 1F, FIG. 1G and FIG. 1H illustrate various stages of an exemplary method for manufacturing an electrical package according to some embodiments of the present disclosure.

FIG. 2A, FIG. 2B, FIG. 2C, FIG. 2D, FIG. 2E, FIG. 2F, FIG. 2G and FIG. 2H illustrate various stages of an exemplary method for manufacturing an electrical package according to some embodiments of the present disclosure.

FIG. 3A and FIG. 3B illustrate various stages of an exemplary method for manufacturing an electrical package according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

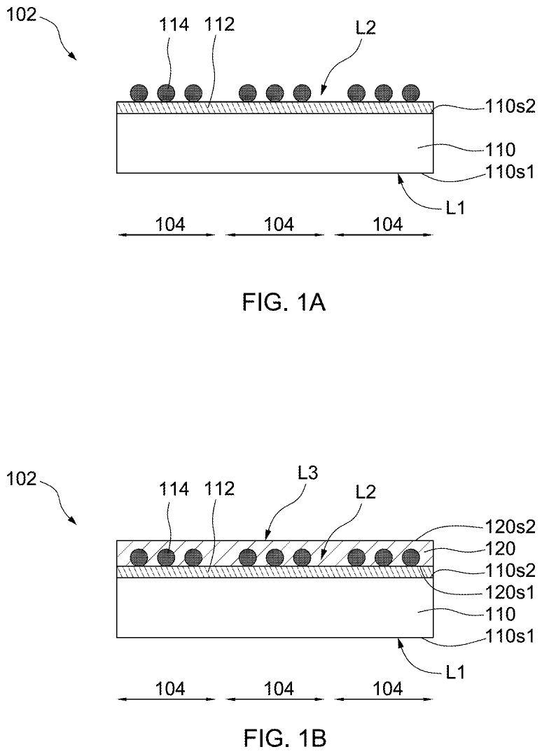

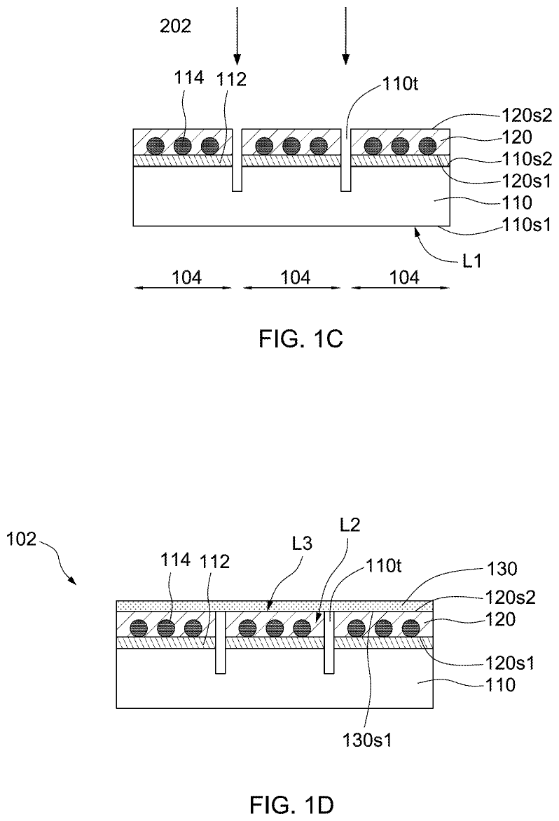

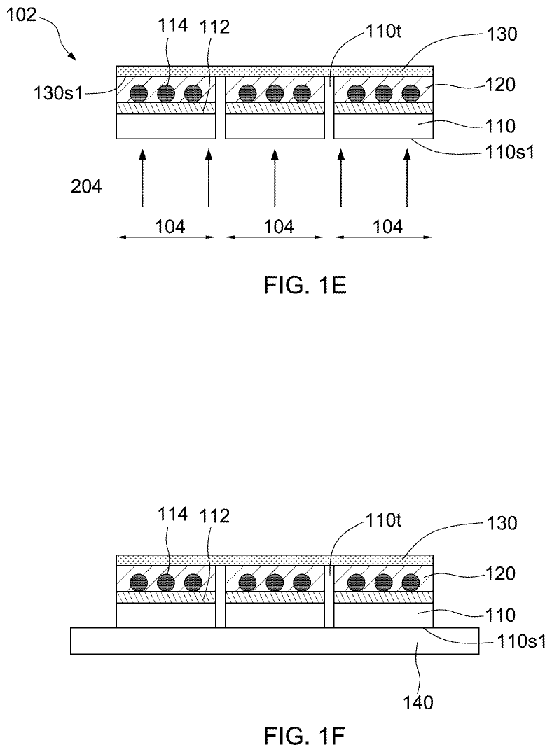

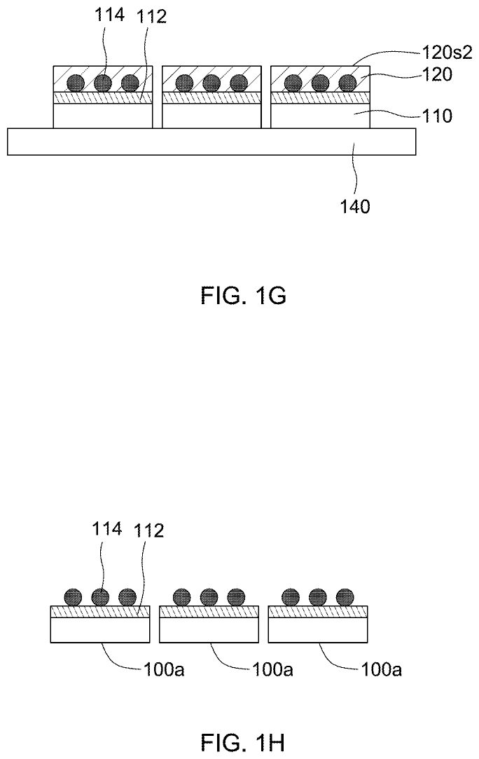

FIG. 1A, FIG. 1B, FIG. 1C, FIG. 1D, FIG. 1E, FIG. 1F, FIG. 1G and FIG. 1H illustrate various stages of an example of a method for manufacturing an electrical package 100a according to some embodiments of the present disclosure.

Referring to FIG. 1A, the method may include providing an electronic structure 102. The electronic structure 102 may include a plurality of electronic units 104. Each of the electronic units 104 may correspond to an electrical package. In some embodiments, each of the electronic units 104 may include a die or a chip, such as a signal processing die (e.g., digital signal processing (DSP) die), a memory die (e.g., dynamic random access memory (DRAM) die, static random access memory (SRAM) die, etc.), a logic die (e.g., application processor (AP), system-on-a-chip (SoC), central processing unit (CPU), graphics processing unit (GPU), microcontroller, etc.), a power management die (e.g., power management integrated circuit (PMIC) die), a radio frequency (RF) die, a sensor die, a micro-electro-mechanical-system (MEMS) die, a front-end die (e.g., analog front-end (AFE) dies) or other active components. In some embodiments, the electronic component supporter 140 may include a plurality of transistors, diodes, or other active components. The transistor may include bipolar junction transistor, MOSFET, JFET or other transistors. The diode may include Zener diode, photodiode, Schottky diode or other diodes.

The electronic structure 102 may include a substrate 110. In some embodiments, the substrate 110 may include a semiconductor carrier, a glass carrier, a ceramic carrier or other suitable carriers. For example, the substrate 110 may include a wafer, which may include silicon; germanium; a compound semiconductor including silicon carbide, gallium arsenic, gallium phosphide, indium phosphide, indium arsenide, and/or indium antimonide; an alloy semiconductor including SiGe, GaAsP, AlinAs, AlGaAs, GalnAs, GaInP, and/or GaInAsP; or combinations thereof. Further, one or more integrated circuits (ICs) are formed within the substrate 110.

In some embodiments, the substrate 110 may have a surface 110s1 and a surface 110s2 opposite thereto. In some embodiments, the surface 110s1 may be a backside surface. In some embodiments, the surface 110s2 may be an active surface. In this disclosure, the term “active surface” may refer to a surface that can output signal, including electronic or optical signal. In some embodiments, the term “active surface” may refer to an electronic component on which contact terminals, such as contact pads, are disposed to receive or transmit signals.

In some embodiments, the electronic structure 102 may include a redistribution structure 112. The redistribution structure 112 may be disposed on the surface 110s2 of the substrate 110. The electronic structure 102 may include at least one dielectric layer, with metal traces as well as vias embedded therein.

In some embodiments, the electronic structure 102 may include a plurality of terminals 114. Each terminal 114 may protrude from the surface 110s2 of the substrate 110 such that the electronic structure 102 has an uneven surface on the surface 110s2. The terminals 114 may be disposed on the surface 110s2 of the substrate 110. The terminals 114 may be disposed on the redistribution structure 112. In some embodiments, each of the terminals 114 may include a bump. The bump may include lead or may be lead-free (e.g., including one or more materials such as alloys of gold and tin solder or alloys of silver and tin solder).

The surface 110s1 may have a level difference (or unevenness) L1. The surface 110s2 may have a level difference (or unevenness) L2. In some embodiments, L2 is greater than L1. In some embodiments, the surface 110s2 may include an uneven surface. In this disclosure, the level difference may refer to a relief from a surface. For example, the level difference may refer to, but is not limited to, a maximum height difference between the highest and lowest points of the surface. In some embodiments, L1 may be less than 30 μm, such as 30 μm, 20 μm, 10 μm, or less. In some embodiments, L2 may be greater than or equal to 80 μm, such as 80 μm, 100 μm, 120 μm, 140 μm, 160 μm, 180 μm, 200 μm, 220 μm or more. In this embodiments, L2 may be defined by the size of the terminal 114.

Referring to FIG. 1B, a leveling layer 120 is provided or formed on the surface 110s2 of the substrate 110. The leveling layer 120 may be configured to provide a relatively smooth surface to allow elements, such as a tape, to be conformally disposed on the aforesaid smooth surface. In some embodiments, the leveling layer 120 may include an adhesive layer or other suitable elements. The leveling layer 120 may include a surface 120s1, which is conformally attached to or in contact with the surface 110s2 of the substrate 110. The leveling layer 120 may include a surface 120s2 opposite to the surface 120s1 and spaced apart from the surface 110s2. The leveling layer 120 may be configured to cover the surface 110s2 and provides a relative smooth surface 120s2. The leveling layer 120 may cover the terminals 114. The leveling layer 120 may fully cover the terminals 114. The leveling layer 120 may fully encapsulate the terminal 114, and there is few or no voids as well as gaps formed between the terminal 114 and the leveling layer 120. The surface 120s2 of the leveling layer 120 may have a level difference (or unevenness) L3. In some embodiments, L3 is smaller than L2. For example, L3 may be smaller than or equal to 30 μm, such as 30 μm, 20 μm, 10 μm, 5 μm, 3 μm, 1 μm or less. The surface 120s2 of the leveling layer 120 may be a relatively flat surface.

In some embodiments, the leveling layer 120 may include a liquid glue or other suitable fluid materials configured to provide a relatively smooth surface. In some embodiments, the leveling layer 120 may include thermally sensitive material, optically sensitive material or other suitable materials, which may be cured by heating or by illuminating light. In some embodiments, the leveling layer 120 may include a solid component, a liquid component and other suitable components. The solid component may include resin, such as epoxy acrylate resin or other suitable materials. The liquid component may include an organic solvents or solutions, such as acrylic acid, its derivatives, or other suitable materials.

In some embodiments, the method may include performing a curing operation or baking operation to cure the leveling layer 120. After the curing operation or baking operation, the liquid component of the leveling layer 120 may be evaporated and removed from the leveling layer 120. As a result, the solid component of the leveling layer 120 remains. The temperature and process time of the curing operation may depend on the liquid components of the leveling layer 120, and are not intended to be limiting.

Referring to FIG. 1C, the method may include performing a half-cut operation 202. In some embodiments, the half-cut operation 202 may include removing a portion of the substrate 110 and the leveling layer 120. The removed portions of the substrate 110 may correspond to cutting streets located between the plurality of terminals 114. The half-cut operation 202 may be configured to form a plurality of trenches 110t on the surface 110s2 of the substrate 110. In some embodiments, the trench 110t may pass through the leveling layer 120. In some embodiments, the trench 110t may pass through the redistribution structure 112. In some embodiments, the trench 110t may extend into the substrate 110. The trench 110t may not extend to the surface 110s1 of the substrate 110. That is, the trench 110t is formed on the substrate 110 but does not pass through the substrate 110. In some embodiments, the trench 110t may expose a portion of side surfaces of the substrate 110. In some embodiments, the half-cut operation 202 may be performed, for example, by a saw cutting the substrate 110 and the adhesive materials. However, the present disclosure is not intended to be limiting. In this embodiment, the leveling layer 120 is formed before the half-cut operation 202.

Referring to FIG. 1D, the method may include providing a tape 130 on the surface 120s2 of the leveling layer 120. The tape 130 may cover the trenches 110t. The tape 130 may be configured to protect the electronic structure 102 from damage during subsequent removal. The tape 130 may include, for example, a back grinding (BG) tape. In some embodiments, the tape 130 may include a surface 130s1 abutting to the surface 120s2 of the leveling layer 120. Since the level difference of the surface 120s2 of the leveling layer 120 is small, the surface 120s of the leveling layer 120 may be substantially flat and the tape 130 may conform to the surface 120s2 of the leveling layer 120 smoothly. In some embodiments, there may be no gaps or voids formed between the surface 130s1 of the tape 130 and the surface 120s2 of the leveling layer 120. In other embodiments, the tape 130 may be replaced by a carrier, which has a rigidity greater than that of the tape 130, and the surface 120s2 of the leveling layer 120 is in contact with the carrier.

Referring to FIG. 1E, the method may include performing a removing operation 204 on the surface 110s1 of the substrate 110 such that the trenches 110t are exposed on the backside of the substrate 110. In some embodiments, the removing operation 204 may be configured to separate the plurality of electronic units 104 from each other. The removing operation may reduce the thickness of the substrate 110. After the removing operation, the trenches 110t pass through the substrate 110, and thus they are exposed on the backside of the substrate 110. In some embodiments, the removing operation 204 may include a grinding operation, such as a chemical mechanical planarization (CMP). In some embodiments, the removing operation 204 may include a depressurizing operation to reduce the pressure of a chamber where the electronic structure 102 is disposed. In some embodiments, the removing operation 204 may be performed at a vacuum pressure or at a near-vacuum pressure. The surface 130s1, corresponding to where the trenches 110t are located, of the tape 130 may be exposed after performing the removing operation 204.

Referring to FIG. 1F, the method may include disposing the surface 110s1 of the substrate 110 on a supporter 140. The supporter 140 may include a glass supporter, a ceramic supporter, a plastic supporter, or other suitable supporters.

Referring to FIG. 1G, the method may include removing the tape 130 from the leveling layer 120 such that the surface 120s2 of the leveling layer 120 may be exposed.

Referring to FIG. 1H, the method may include removing the leveling layer 120 and the supporter 140 to produce a plurality of electrical packages 100a. In some embodiments, removing the leveling layer 120 may be performed by using a mechanical method. For example, the leveling layer 120 may be attached to a tape or support, and then the leveling layer 120 may be removed by an external force from machine or manpower. In other some embodiments, removing the leveling layer 120 may be performed by using a chemical method. For example, the leveling layer 120 may be removed by a de-glue solution. The de-glue solution may be configured to dissolve the solid component and residue of liquid component of the leveling layer 120. The de-glue solution may include organic solutions or other suitable solutions.

In a comparative example, a tape (e.g., a BG tape) is formed on an uneven surface of a carrier, which has height difference equal to or greater than 80 μm. In some conditions, the BG tape cannot compensate the height difference of the carrier, resulting in failure of the BG tape being conformally attached to aforesaid uneven surface of the carrier. As a result, voids and gaps are formed between the BG tape and the carrier. When a grinding operation is performed, the pressure in the chamber is reduced. During reduction of pressure, moisture or other substances may infiltrate into the said voids and gaps, which may adversely affect yield. In this embodiment, the leveling layer 120 is provided on an uneven surface (e.g., the surface 110s2) of the substrate 110 to compensate the height difference on the surface 110s2 of the substrate 110. The leveling layer 120 can provide a relatively smooth surface (e.g., the surface 120s2) to which the tape 130 can be conformally attached. In this embodiment, during the removing operation 204, the tape 130 may be tightly and conformally attached to the surface 120s2 of the leveling layer 120 even in pressure-decreasing environments. As a result, fewer or no voids or gaps are formed between the tape 130 and the leveling layer 120. As a result, the protective ability of the tape 130 can be enhanced during the removing operation 204. Further, residue of the BG tape may remain on the terminals and the redistribution structure when the BG tape is directly attached to the terminals. In comparison with direct attachment of the BG tape to the terminals, the leveling layer 120 of the present disclosure can be removed more completely.

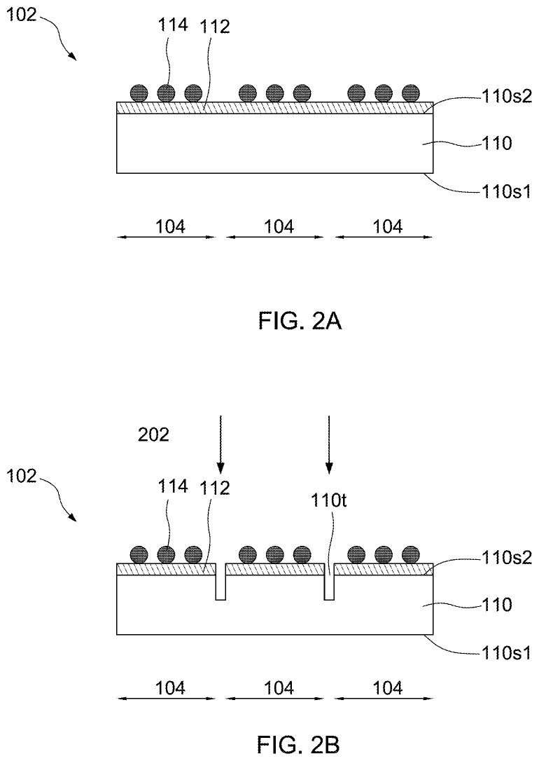

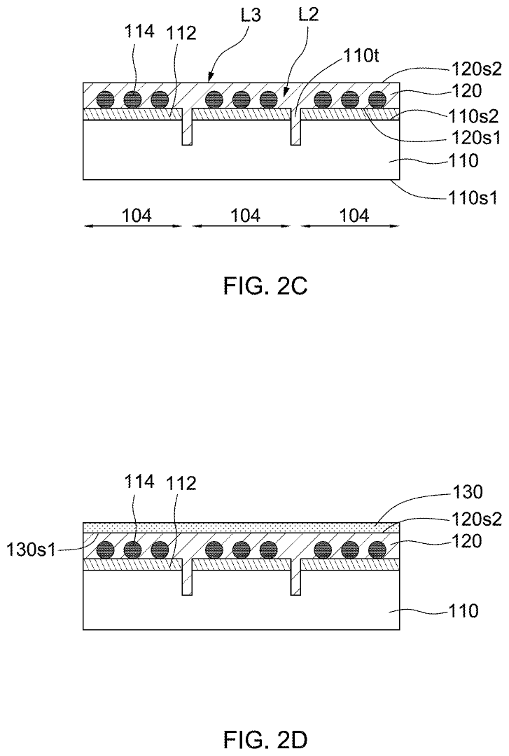

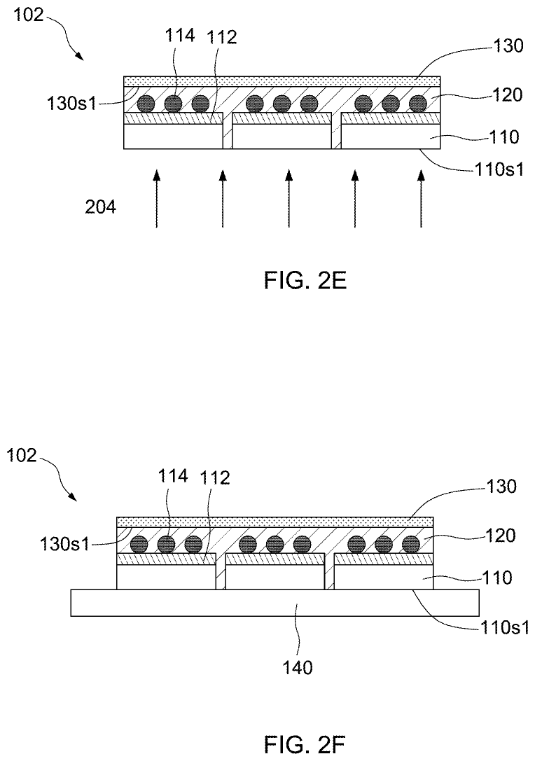

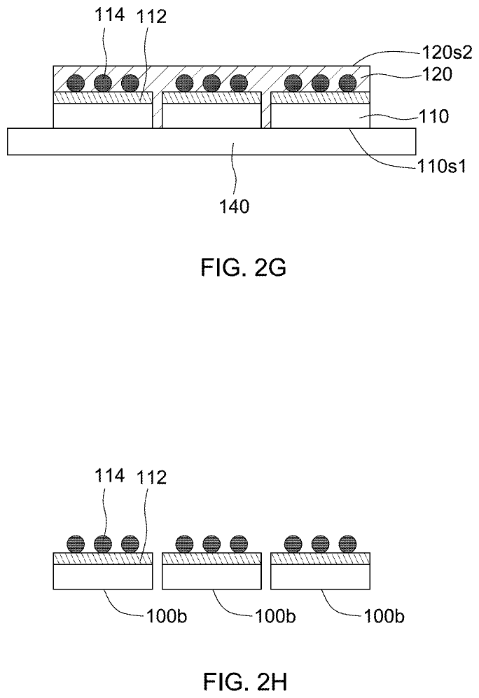

FIG. 2A, FIG. 2B, FIG. 2C, FIG. 2D, FIG. 2E, FIG. 2F, FIG. 2G and FIG. 2H illustrate various stages of an example of a method for manufacturing an electrical package 100b according to some embodiments of the present disclosure.

Referring to FIG. 2A, the method may include providing an electronic structure 102. The electronic structure 102 may include a plurality of electronic units 104. Each of the electronic units 104 may correspond to an electrical package after the electronic structure 102 is divided. The electronic structure 102 may include a substrate 110, a redistribution structure 112, and terminals 114. The substrate 110 may include a surface 110s1 and a surface 110s2 opposite the surface 110s1.

Referring to FIG. 2B, the method may include performing a half-cut operation 202 on the surface 110s2 to form a plurality of trenches 110t between the plurality of electronic units 104. The trench 110t may pass through the redistribution structure 112. The trench 110t may extend into the substrate 110 and may not extend to the surface 110s1 of the substrate 110. That is, the trench 110t is formed on the substrate 110 but does not pass through the substrate 110.

Referring to FIG. 2C, the method may include providing or forming a leveling layer 120 on the surface 110s2 of the substrate 110. In some embodiments, the leveling layer 120 may include a liquid glue or other fluid materials. In some embodiments, the leveling layer 120 may fill into the trenches 110t. The leveling layer 120 may be formed between the plurality of electronic units 104 and thus surround the electronic units 104. The leveling layer 120 may include a surface 120s1 conformally formed on the surface 110s2 of the substrate 110 and a surface 120s2 opposite to the surface 120s1. The surface 120s2 of the leveling layer 120 may have a level difference L3 smaller than a level difference L2 of the surface 110s2 of the substrate 110. In some embodiments, the method may include curing the leveling layer 120.

Referring to FIG. 2D, the method may include providing a tape 130 on the surface 120s2 of the leveling layer 120. In some embodiments, the tape 130 may include a surface 130s1 abutting to the surface 120s2 of the leveling layer 120. Since the level difference of the surface 120s2 of the leveling layer 120 is small, the surface 102s of the leveling layer 120 may be substantially flat and the tape 130 may conform to the surface 120s2 of the leveling layer 120 smoothly. In some embodiments, no gaps or voids may be formed between the surface 130s1 of the tape 130 and the surface 120s2 of the leveling layer 120.

Referring to FIG. 2E, the method may include performing a removing operation 204 on the surface 110s1 of the substrate 110 such that the leveling layer 120 and the trenches 110t are exposed on the backside of the substrate 110. In some embodiments, the removing operation 204 may include a grinding operation, such as chemical mechanical planarization (CMP). In some embodiments, the removing operation 204 may include a depressurizing operation to reduce the pressure of a chamber where the electronic structure 102 is disposed. In some embodiments, the removing operation 204 may be performed at vacuum or near-vacuum pressure. After the removing operation, the trenches 110t pass through the substrate 110, and thus they are exposed on the backside of the substrate 110. Further, the leveling layer 120 filled into the trenches 110t may be exposed as well.

Referring to FIG. 2F, the method may include disposing the surface 110s1 of the substrate 110 on a supporter 140. The supporter 140 may include a glass support, a ceramic support, a plastic support or other suitable supports.

Referring to FIG. 2G, the method may include removing the tape 130 from the leveling layer 120 such that the surface 120s2 of the leveling layer 120 may be exposed.

Referring to FIG. 2H, the method may include removing the leveling layer 120 and the supporter 140 to produce a plurality of electrical packages 100b. In some embodiments, removing the leveling layer 120 may be performed by using a mechanical method. For example, the leveling layer 120 may be attached to a tape or support, and then the leveling layer 120 may be removed by an external force. In other some embodiments, removing the leveling layer 120 may be performed by using a de-glue solution. The de-glue solution may be configured to dissolve the solid component and the residue of liquid component of the leveling layer 120.

In this embodiment, the half-cut operation 202 may be performed before forming the leveling layer 120 on the surface 110s2 of the substrate 110. In this embodiment, the leveling layer 120 is provided on an uneven surface (e.g., the surface 110s2) of the substrate 110 to compensate the height difference on the surface 110s2 of the substrate 110. The leveling layer 120 can provide a relatively smooth surface (e.g., the surface 120s2) to which tape 130 can be conformally attached. In this embodiment, during the removing operation 204, the tape 130 may be tightly and conformally attached to the surface 120s2 of the leveling layer 120 even in decreased pressure environments. As a result, fewer or no voids or gaps, which may cause moisture or other substances to infiltrate into, are formed between the tape 130 and the leveling layer 120. As a result, the protective ability of the tape 130 can be enhanced during the removing operation 204.

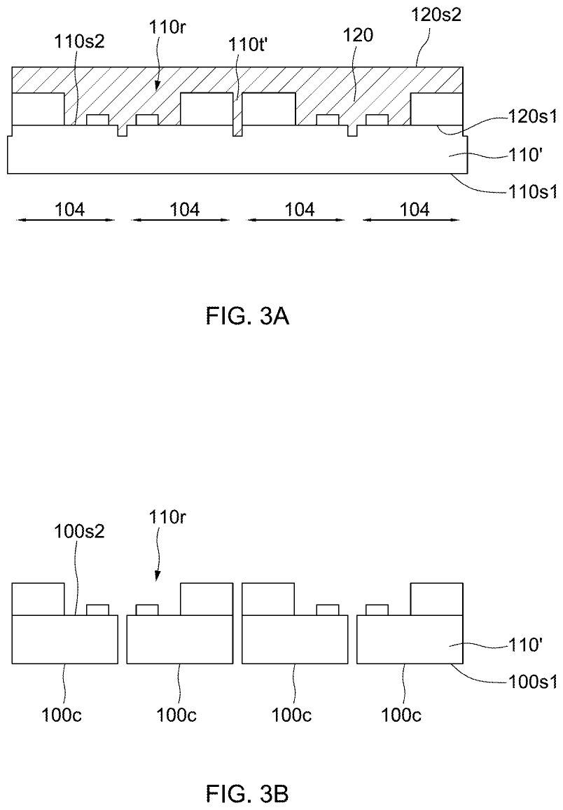

FIG. 3A and FIG. 3B illustrate various stages of an example of a method for manufacturing an electrical package 100c according to some embodiments of the present disclosure.

Referring to FIG. 3A, the electrical package 100c may include a substrate 110′. In some embodiments, the substrate 110′ may be a microelectromechanical systems (MEMS) wafer. Each of the plurality of electronic units 104 may correspond to an electrical package 100c. Each of the trenches 110t′ may formed between adjacent two electronic units 104 and may be formed by a half-cut operation. The substrate 110′ may have a surface 110s1 and a surface 110s2 opposite to the surface 110s1. The surface 110s2 may define a plurality of recess 110r. In some embodiments, the surface 110s2 of the substrate 110′ may have a height difference greater than or equal to 80 μm, such as 80 μm, 100 μm, 120 μm, 140 μm, 160 μm, 180 μm, 200 μm, 220 μm or more.

In this embodiment, an leveling layer 120 may be formed on the surface 110s2 to compensate the height difference of the surface 110s2 of the substrate 110′. The leveling layer 120 may fill the trenches 110t′. The leveling layer 120 may have a surface 120s1 and a surface 120s2. The leveling layer 120 may fill the recess 110r on the surface 110s2 of the substrate 110. The surface 120s1 is conformally formed on the surface 110s2 of the substrate 110. The surface 120s2 may be a substantially flat surface.

Referring to FIG. 3B, the processes from FIG. 3A to FIG. 3B maybe the same as or similar to those illustrated in FIG. 2C, 2D, 2E, 2F, 2G and 2H. A portion of the carrier 100′ (e.g. a back portion of the substrate 110′) may be removed such that the plurality of electrical packages 100c are produced. In this embodiment, the leveling layer 120 can provide a relatively smooth surface (e.g., the surface 120s2) such that a BG tape (not shown) can be conformally attached to such relatively smooth surface. In this embodiment, during a grinding operation, the BG tape may be tightly and conformally attached to the surface 120s2 of the leveling layer 120 even in decreased pressure environments. As a result, fewer or no voids or gaps, which may cause moisture or other substances to infiltrate into, are formed between the BG tape and the leveling layer 120. As a result, the protective ability of the BG tape can be enhanced.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of manufacturing an electrical package, comprising:
providing a substrate having a first surface and a second surface opposite to the first surface, wherein the second surface has a first level difference;
forming an adhesive layer on the second surface of the substrate, wherein the adhesive layer is configured to cover the second surface and provides a third surface spaced apart from the second surface of the substrate, wherein the third surface has a second level difference;
disposing a tape on the third surface of the adhesive layer; and
performing a removing operation on the first surface of the substrate;
wherein the second level difference is smaller than the first level difference.

2. The method of claim 1, wherein the second surface comprises a plurality of bumps, a plurality of recesses or both.

3. The method of claim 1, further comprising:
performing a half-cut operation so as to form a plurality of trenches on the second surface of the substrate.

4. The method of claim 3, wherein the adhesive layer is formed before the half-cut operation, and wherein the trenches passes through the adhesive layer.

5. The method of claim 3, wherein the adhesive layer is formed after the half-cut operation, and the adhesive layer fills into the trenches.

6. The method of claim 1, further comprising:
performing a half-cut operation to form a plurality of trenches on the second surface of the substrate before the removing operation;
wherein the trenches pass through the substrate after the removing operation.

7. The method of claim 1, wherein the removing operation comprises a grinding operation.

8. The method of claim 1, further comprising:
removing the tape; and
removing the adhesive layer, wherein the adhesive layer is removed after removing the tape.

9. A method of manufacturing an electrical package, comprising:
providing a substrate having a first surface and a second surface opposite to the first surface, wherein the substrate comprises a plurality of components and a plurality of recesses on the second surface;
forming an adhesive layer on the second surface of the substrate, wherein the adhesive layer comprises a material configured to surround the component or fill into the recesses;
disposing a tape on the adhesive layer; and
performing a removing operation on the first surface of the substrate.

10. The method of claim 9, further comprising: performing a half-cut operation so as to form a plurality of trenches on the second surface of the substrate.

11. The method of claim 10, wherein the half-cut operation is performed after the adhesive layer is provided, and wherein the trenches extend through the adhesive layer.

12. The method of claim 9, further comprising:
removing the tape; and
removing the adhesive layer.

13. The method of claim 10, wherein the half-cut operation is performed before the adhesive layer is provided, and wherein the adhesive layer fills into the trenches.

14. A method of manufacturing an electrical package, comprising:
providing a substrate having a first surface and a second surface opposite to the first surface, where the second surface has a first unevenness;
forming a leveling layer on the second surface of the substrate and configured to provide a third surface having a second unevenness more even than the first unevenness;
disposing a carrier on the third surface to support the substrate; and
removing at least a portion of the substrate from the first surface of the substrate.

15. The method of claim 14, wherein the first unevenness is defined by either a plurality of bumps or a plurality of recesses at the second surface.

16. The method of claim 15, wherein the leveling layer comprises a material configured to fill between the bumps or fill into the recesses.

17. The method of claim 14, further comprising: performing a half-cut operation on the second surface of the substrate so as to form a plurality of trenches on the second surface of the substrate.

18. The method of claim 17, wherein the half-cut operation is performed after the leveling layer is provided, and wherein the trenches extend through the leveling layer.

19. The method of claim 17, wherein the half-cut operation is performed before the leveling layer is provided, and wherein the leveling layer fills into the trenches.

20. The method of claim 17, wherein the step of disposing the carrier is performed after performing the half-cut operation on the second surface of the substrate.
